(19) United States
(12) Patent Application Publication
(10) Pub. No.: US 2022/0286111 A1
(43) Pub. Date: Sep. 8, 2022

(54) ACOUSTIC RESONATOR FILTER

(71) Applicant: SAMSUNG ELECTRO-MECHANICS CO., LTD., Suwon-si (KR)

(72) Inventor: Hyun Min HWANG, Suwon-si (KR)

(73) Assignee: SAMSUNG ELECTRO-MECHANICS CO., LTD., Suwon-si (KR)

(21) Appl. No.: 17/476,797

(22) Filed: Sep. 16, 2021

(30) Foreign Application Priority Data
Mar. 2, 2021 (KR) 10-2021-0027503

(51) Int. Cl. H03H 9/56; H03H 9/17; H03H 9/54

(52) U.S. Cl. CPC H03H 9/568; H03H 9/17; H03H 9/542

(57) ABSTRACT

An acoustic resonator filter includes a series portion including at least one series acoustic resonator electrically connected, in series, between first and second ports of the acoustic resonator filter configured to pass a radio-frequency (RF) signal from the first port to the second port, a shunt portion including a plurality of shunt acoustic resonators electrically connected to each other, in anti-series, between one node of the series portion and a ground, and a DC voltage terminal configured to generate a DC voltage across at least one of the plurality of shunt acoustic resonators by an electrical connection of the DC voltage terminal to a first electrode of the at least one of the plurality of shunt acoustic resonators and to a different second electrode of the at least one of the plurality of shunt acoustic resonators. A DC voltage may be generated across the at least one series acoustic resonator.

### CROSS-REFERENCE TO RELATED APPLICATION

This application claims the benefit under 35 USC 119(a) of Korean Patent Application No. 10-2021-0027503 filed on Mar. 2, 2021 in the Korean Intellectual Property Office, the entire disclosure of which is incorporated herein by reference for all purposes.

### BACKGROUND

### 1. Field

The present disclosure relates to an acoustic resonator filter.

### 2. Description of Related Art

Mobile communication devices, chemical and biological testing devices, and other electronic devices, use small and lightweight filters, oscillators, resonant elements, and/or acoustic resonant mass sensors.

An acoustic resonator such as an acoustic wave (BAW) filter may be configured as such a small and lightweight filter, oscillator, resonant element, and acoustic resonant mass sensor, as well as other components, since the acoustic resonator is small and has improved performance compared to a dielectric filter, a metal cavity filter, and a waveguide, for example. Such an acoustic resonator may be used in communication modules of modern mobile devices that provide high performance (for example, wide pass bandwidth).

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an acoustic resonator filter includes a series portion of the acoustic resonator filter, the series portion including at least one series acoustic resonator electrically connected, in series, between first and second ports of the acoustic resonator filter configured to pass a radio-frequency (RF) signal from the first port to the second port, a shunt portion of the acoustic resonator filter, the shunt portion including a plurality of shunt acoustic resonators electrically connected to each other, in anti-series, between one node of the series portion and a ground, and a DC voltage terminal configured to generate a DC voltage across at least one of the plurality of shunt acoustic resonators by an electrical connection of the DC voltage terminal to a first electrode of the at least one of the plurality of shunt acoustic resonators and to a different second electrode of the at least one of the plurality of shunt acoustic resonators.

The DC voltage terminal may be configured to generate the DC voltage between a node, between two of the plurality of shunt acoustic resonators, and the ground.

The DC voltage terminal may be configured to generate a first DC voltage across at least one first shunt acoustic resonator of the at least one of the plurality of shunt acoustic resonators that is different from a DC voltage across at least one other shunt acoustic resonator of the plurality of shunt acoustic resonators when the first DC voltage is generated.

The at least one series acoustic resonator may include a plurality of series acoustic resonators, and the DC voltage terminal may be further configured to generate another DC voltage across at least one of the plurality of series acoustic resonators by another electrical connection of the DC voltage terminal to a first electrode of the at least one of the plurality of series acoustic resonators and to a different second electrode of the at least one of the plurality of series acoustic resonators.

With the DC voltage terminal configured to generates the DC voltage, a difference between a plurality of anti-resonant frequencies of the plurality of shunt acoustic resonators may be smaller than a difference between a plurality of resonant frequencies of the plurality of shunt acoustic resonators when the DC voltage is generated.

The DC voltage terminal may be configured to generate the DC voltage to have a magnitude greater than 10V.

The DC voltage terminal may be further configured to generate the DC voltage to have a magnitude of 50V or less.

The acoustic resonator filter may further include a capacitor connected electrically, in parallel, with one or more shunt acoustic resonators of the at least one of the plurality of shunt acoustic resonators.

The at least one of the plurality of shunt acoustic resonators may include two or more of the plurality of shunt acoustic resonators, and the one or more shunt acoustic resonators may be a single shunt acoustic resonator.

In one general aspect, an acoustic resonator filter includes a series portion of the acoustic resonator filter, the series portion including a plurality of series acoustic resonators electrically connected, in anti-series, between first and second ports of the acoustic resonator filter configured to pass a radio-frequency (RF) signal from the first port to the second port, a shunt portion of the acoustic resonator filter, the shunt portion including at least one shunt acoustic resonator electrically connected between one node of the series portion and a ground, and a DC voltage terminal configured to generate a DC voltage across at least one of the plurality of series acoustic resonators by an electrical connection of the DC voltage terminal to a first electrode of the at least one of the plurality of series acoustic resonators and to a different second electrode of the at least one of the plurality of series acoustic resonators.

The DC voltage terminal may be configured to generate a first DC voltage across at least one first series acoustic resonator of the at least one of the plurality of series acoustic resonators that is different from a DC voltage across at least one other series acoustic resonator of the plurality of series acoustic resonators when the first DC voltage is generated.

With the DC voltage terminal configured to generates the DC voltage, a difference between a plurality of anti-resonant frequencies of the plurality of series acoustic resonators may be smaller than a difference between a plurality of resonant frequencies of the plurality of series acoustic resonators when the DC voltage is generated.

The DC voltage terminal may be configured to generate the DC voltage to have a magnitude greater than 10V.

In one general aspect, an acoustic resonator includes a series portion of the acoustic resonator filter, the series portion including at least one series acoustic resonator electrically connected, in series, between first and second ports of the acoustic resonator filter configured to pass a radio-frequency (RF) signal from the first port to the second port, a shunt portion of the acoustic resonator filter, the shunt portion including a plurality of shunt acoustic resonators electrically connected to each other between one node of the series portion and a ground, and a DC voltage terminal configured to generate a DC voltage across at least one of the plurality of shunt acoustic resonators by an electrical connection of the DC voltage terminal to a first electrode of the at least one of the plurality of shunt acoustic resonators and to a different second electrode of the at least one of the plurality of shunt acoustic resonators, where, with the DC voltage terminal configured to generates the DC voltage, a difference between a plurality of anti-resonant frequencies of the plurality of shunt acoustic resonators is smaller than a difference between a plurality of resonant frequencies of the plurality of shunt acoustic resonators when the DC voltage is generated.

With the DC voltage terminal configured to generates the DC voltage, the difference between the plurality of resonant frequencies of the plurality of shunt acoustic resonators may be smaller than a difference between a resonant frequency, among the plurality of resonant frequencies, and a resonant frequency of the at least one series acoustic resonator when the DC voltage is generated, and the resonant frequency, among the plurality of resonant frequencies, may be higher than the resonant frequency of the at least one series acoustic resonator.

The series portion and the shunt portion may provide a pass band, each of the plurality of anti-resonant frequencies of the plurality of shunt acoustic resonators may be positioned within the pass band, and each of the plurality of resonant frequencies of the plurality of shunt acoustic resonators may be positioned outside the pass band.

The DC voltage terminal may be configured to generate the DC voltage between a node, between two of the plurality of shunt acoustic resonators, and the ground.

The DC voltage terminal may be configured to generate the DC voltage to have a magnitude greater than 10V.

The DC voltage terminal may be further configured to generate the DC voltage to have a magnitude of 50V or less.

The acoustic resonator filter may further include a capacitor connected electrically, in parallel, with one or more shunt acoustic resonators of the plurality of shunt acoustic resonators.

Other features and aspects will be apparent from the following detailed description, the drawings, and the claims.

### BRIEF DESCRIPTION OF DRAWINGS

FIGS. 1A to 1E are circuit diagrams of acoustic resonator filters according to one or more embodiments.

FIGS. 2A to 2F are views illustrating example trimming of a shunt acoustic resonator of an acoustic resonator filter according to one or more embodiments.

FIGS. 3A and 3B are graphs illustrating removal of a notch for various example trimmings of a shunt acoustic resonator of an acoustic resonator filter according to one or more embodiments.

FIGS. 4A and 4B are graphs illustrating removal of a notch and a second harmonic wave depending on example trimmings of a shunt acoustic resonator of an acoustic resonator filter according to one or more embodiments.

FIG. 5A is a plan view illustrating an example structure of an acoustic resonator which may be included in an example acoustic wave resonator filter according to one or more embodiments, FIG. 5B is an example cross-sectional view taken along line I-I′ of FIG. 5A, FIG. 5C is an example cross-sectional view taken along line II-II′ of FIG. 5A, and FIG. 5D is an example cross-sectional view taken along line III-III′ of FIG. 5A.

Throughout the drawings and the detailed description, the same reference numerals refer to the same or like elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known or understood after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. Hereinafter, while various embodiments of the disclosure of this application will be described in detail with reference to the accompanying drawings, it is noted that examples are not limited to the same.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. As used herein “portion” of an element may include the whole element or less than the whole element.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as illustrated in the figures, for example. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure of this application. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Herein, it is noted that use of the term “may” with respect to an example, for example, as to what an example may include or implement, means that at least one example exists in which such a feature is included or implemented while all examples are not limited thereto.

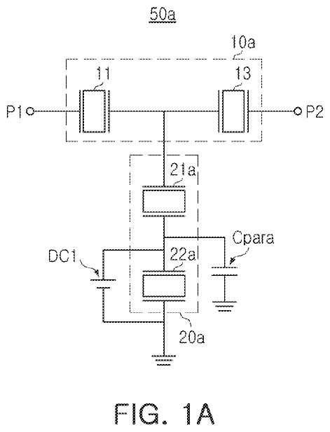

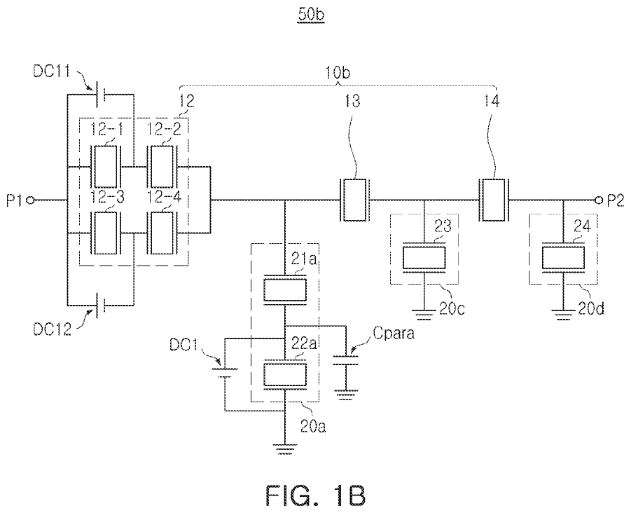

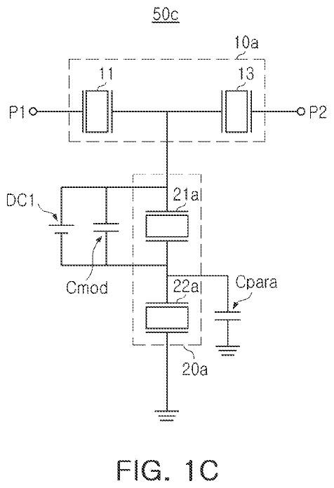

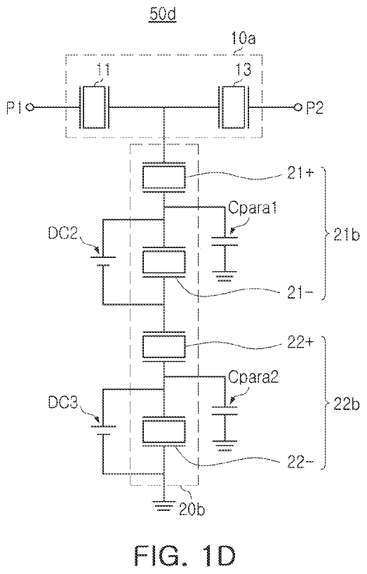

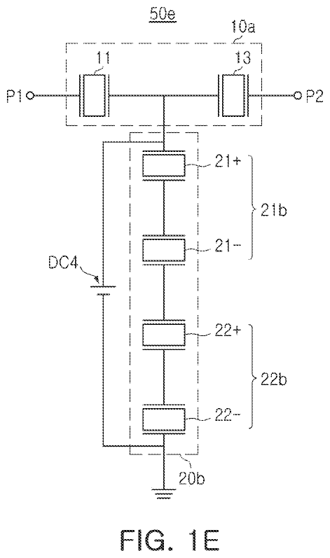

FIGS. 1A to 1E are circuit diagrams of acoustic resonator filters according to one or more embodiments.

Referring to FIG. 1A, an acoustic resonator filter 50a according to one or more embodiments may include a series part 10a and a shunt part 20a. A radio-frequency (RF) signal may be allowed to pass through a first port P1 and a second port P2, or may be blocked between the first port P1 and the second port P2, depending on a frequency of the RF signal.

Referring to FIG. 1A, the series part 10a may include one or more series acoustic resonators 11 and 13, and the shunt part 20a may include one or more shunt acoustic resonators 21a and 22a.

Electrical connection nodes between the one or more series acoustic resonators 11 and 13, between the one or more shunt acoustic resonators 21a and 22a, and between the series part 10a and the shunt part 20a may be implemented with a material having a relatively low resistivity, such as gold (Au), a gold-tin (Au—Sn) alloy, copper (Cu), a copper-tin (Cu—Sn) alloy, aluminum (Al), an aluminum alloy, or the like, but embodiments are not limited thereto.

The one or more series acoustic resonators 11 and 13 and the one or more shunt acoustic resonator 21a and 22a may each convert electrical energy of the RF signal into mechanical energy through piezoelectric properties, and may convert mechanical energy into electrical energy through the piezoelectric properties. As the frequency of the RF signal becomes closer to a resonant frequency of the acoustic resonator, an energy transfer rate between a plurality of electrodes may be significantly increased. As the frequency of the RF signal becomes closer to an anti-resonant frequency of the acoustic resonator, the energy transfer rate between the plurality of electrodes may be significantly decreased. The anti-resonant frequency of the acoustic resonator may be higher than the resonant frequency of the acoustic resonator.

For example, the one or more series acoustic resonators 11 and 13 and the one or more shunt acoustic resonators 21a and 22a may each be a film bulk acoustic resonator (FBAR) or a solidly mounted resonator (SMR) type resonator, for example.

The one or more series acoustic resonator 11 and 13 may be electrically connected, in series, between the first and second ports P1 and P2. As the frequency of the RF signal becomes closer to the resonant frequency, a pass rate of the RF signal between the first and second ports P1 and P2 may be increased. As the frequency of the RF signal becomes closer to the anti-resonant frequency, the pass rate of the RF signal between the first and second ports P1 and P2 may be decreased.

The one or more shunt acoustic resonators 21a and 22a may be electrically shunt-connected between the one or more series acoustic resonators 11 and 13 and a ground. A pass rate of the RF signal to the ground may be increased as the frequency of the RF signal becomes closer to the resonant frequency, and may be decreased as the frequency of the RF signal becomes closer to the anti-resonant frequency.

The pass rate of the RF signal between the first and second ports P1 and P2 may be decreased as the pass rate of the RF signal to the ground is increased. The pass rate of the RF signal between the first and second ports P1 and P2 may be increased as the pass rate of the RF signal to the ground is decreased.

That is, the pass rate of the RF signal between the first and second ports P1 and P2 may be decreased as the frequency of the RF signal becomes closer to the resonant frequency of the one or more shunt acoustic resonators 21a and 22a or closer to the anti-resonant frequency of the one or more series acoustic resonators 11 and 13.

Since the anti-resonant frequency is higher than the resonant frequency, the acoustic resonator filter 50a may have a pass bandwidth having a lowest frequency corresponding to a resonant frequency of the one or more shunt acoustic resonators 21a and 22a and a highest frequency corresponding to the anti-resonant frequency of the one or more series acoustic resonators 11 and 13.

The pass bandwidth may be increased as a difference between the resonant frequency of the one or more shunt acoustic resonators 21a and 22a and the anti-resonant frequency of the one or more series acoustic resonators 11 and 13 is increased. However, when the difference is significantly large, the pass bandwidth may be split and insertion loss of the pass bandwidth may be increased.

When the resonant frequency of the one or more series acoustic resonators 11 and 13 is appropriately higher than the anti-resonant frequency of the one or more shunt acoustic resonators 21a and 22a, a bandwidth of the acoustic resonator filter 50a may be large but not split, or insertion loss may be reduced.

In an acoustic resonator, a difference between a resonant frequency and an anti-resonant frequency may be determined based on kt² (electromechanical coupling factor), physical properties of the acoustic resonator, and the resonant frequency and the anti-resonant frequency may be changed together when a size or shape of the acoustic resonator is changed.

Since the pass bandwidth of the acoustic resonator filter 50a may have a characteristic proportional to an overall frequency of the pass bandwidth, the pass bandwidth may become larger as the overall frequency of the pass bandwidth is higher.

However, the higher the overall frequency of the pass bandwidth, the shorter the wavelength of the RF signal passing through the acoustic resonator filter 50a. The shorter the wavelength of the RF signal, the greater the energy attenuation compared with a transmission/reception distance in a remote transmission/reception process at an antenna.

That is, as the overall frequency of the pass bandwidth of the acoustic resonator filter 50a is higher, the RF signal passing through the acoustic resonator filter 50a may have higher power for stability and/or smoothness of the remote transmission/reception process, e.g., compared to examples where the pass bandwidth of the acoustic resonator filter 50a is lower.

As the power of the RF signal passing through the acoustic resonator filter 50a is increased, heat generated by a piezoelectric operation of each of the one or more shunt acoustic resonators 21a and 22a and the one or more series acoustic resonators 11 and 13 may be increased, and there may be a high probability of damage caused by the heat generation of each of the one or more shunt acoustic resonators 21a and 22a and the one or more series acoustic resonators 11 and 13.

The shunt part 20a may include a plurality of shunt acoustic resonators 21a and 22a electrically connected between one node of the series part 10a and a ground. For example, the plurality of shunt acoustic resonators 21a and 22a may be connected to each other in series and/or parallel.

As the number of the plurality of shunt acoustic resonators 21a and 22a included in the shunt part 20a is increased, heat generation of each of the plurality of shunt acoustic resonators 21a and 22a may be reduced, and there may be a lower probability of damage caused by the heat generation of each of the plurality of shunt acoustic resonators 21a and 22a.

The plurality of shunt acoustic resonators 21a and 22a may be connected to each other in anti-series. For example, among a plurality of first electrodes and a plurality of second electrodes of each of the plurality of shunt acoustic resonators 21a and 22a, a plurality of electrodes connected closer to each other may all be disposed below a piezoelectric layer or above the piezoelectric layer. For example, considering that each of the shunt acoustic resonators 21a and 22a includes an upper electrode and a lower electrode, the anti-series connection may have the respective upper electrodes face or oppose (electrically connect to) each other or have the respective lower electrodes face or oppose (electrically connect to) each other, e.g., the lower electrode of shunt acoustic resonator 21a electrically connects with the lower electrode of shunt acoustic resonator 22a, or the upper electrode of shunt acoustic resonator 21a electrically connects with the upper electrode of shunt acoustic resonator 22a, in various embodiments.

Accordingly, among harmonics mixed in the RF signal passing through the acoustic resonator filter 50a, even-order harmonics may be removed, and thus, linearity of the RF signal may be further improved.

However, as the number of the plurality of shunt acoustic resonators 21a and 22a is increased, process distribution parameters between the plurality of shunt acoustic resonators 21a and 22a may be increased or diversified. The process distribution parameters may act as a limitation in improving performance (for example, insertion loss, attenuation characteristics, skirt characteristics, and a bandwidth span) of the acoustic resonator filter 50a.

For example, the process distribution parameters between the plurality of shunt acoustic resonators 21a and 22a may be modeled as a parasitic capacitor Cpara connected, in parallel, to one of the plurality of shunt acoustic resonators 22a. Due to the parasitic capacitor Cpara, an anti-resonant frequency of one shunt acoustic resonator 22a, among the plurality of shunt acoustic resonators, may be decreased. Accordingly, since some of the plurality of shunt acoustic resonators 21a and 22a may act as a bottleneck for power of the RF signal, there may be a high probability of damage caused by heat generation. Alternatively, since removal efficiency of even-order harmonics, among harmonics mixed in the RF signal, may be reduced, the linearity of the RF signal may be reduced and the insertion loss may be increased.

Referring to FIG. 1A, an acoustic resonator filter 50a according to one or more embodiments may further include a DC voltage terminal DC1 electrically connected to at least one of the plurality of shunt acoustic resonators 21a and 22a to generate a DC voltage between first and second electrodes of one shunt acoustic resonator 22a, among the plurality of shunt acoustic resonators.

Since the parasitic capacitor Cpara serves to further bias a distribution of electrons between the first and second electrodes of one shunt acoustic resonator 22a, among the plurality of shunt acoustic resonators, a DC voltage on a DC voltage terminal DC1 may bias the distribution of the electrons between the first and second electrodes in a direction opposing a bias direction of electronics depending on the parasitic capacitor Cpara. That is, since the DC voltage on the DC voltage terminal DC1 may cancel an effect of the parasitic capacitor Cpara between the first and second electrodes of one shunt acoustic resonator 22a, among the plurality of shunt acoustic resonators, the acoustic resonator filter 50a may reduce the process distribution parameters corresponding to the parasitic capacitor Cpara.

Accordingly, since the probability of damage caused by heat generation of some of the plurality of shunt acoustic resonators 21a and 22a may be reduced, power durability of the acoustic resonator filter 50a according to one or more embodiments may be further increased. Alternatively, since removal efficiency of even-order harmonics, among harmonics mixed in the RF signal passing through the acoustic resonator filter 50a according to one or more embodiments may be improved, the linearity of the RF signal may be increased and the insertion loss may also be reduced.

For example, the DC voltage terminal DC1 may be implemented as, or representative of, a battery included in the acoustic resonator filter 50a, and may be electrically connected to an external power management integrated circuit (IC) of the acoustic resonator filter 50a to receive a DC voltage from the power management IC. For example, the battery may be disposed on an upper side of a substrate on which an acoustic resonator is disposed and may be disposed in a cap coupled to the substrate to accommodate the acoustic resonator. For example, the power management IC may be electrically connected to a metal via penetrating through the substrate, and the metal via may be electrically connected to an acoustic resonator.

For example, the DC voltage terminal DC1 may be electrically connected to, i.e., across, at least one of the plurality of shunt acoustic resonators 21a and 22a to generate a DC voltage between a ground and a node between the plurality of shunt acoustic resonators 21a and 22a. Accordingly, a structure of the DC voltage terminal DC1 may be further simplified, and a DC voltage of one shunt acoustic resonator 22a, among the plurality of shunt acoustic resonators, may be stably generated.

For example, the DC voltage terminal DC1 may be electrically connected to at least one of the plurality of shunt acoustic resonators 21a and 22a such that a DC voltage between first and second electrodes of one shunt acoustic resonator 22a, among the plurality of shunt acoustic resonators, is different from a DC voltage between first and second electrodes of another shunt acoustic resonator. Accordingly, the DC voltage terminal DC1 may more effectively cancel the effect of the parasitic capacitor Cpara.

Referring to FIG. 1B, a series part 10b of an acoustic resonator filter 50b according to one or more embodiments may include a plurality of series acoustic resonators 12, including series acoustic resonators 12-1, 12-2, 12-3, and 12-4, and series acoustic resonators 13 and 14. In a non-limiting example, a plurality of the series acoustic resonators 12, e.g., series acoustic resonators 12-1, 12-2, 12-3, and 12-4, 13, and 14, may be connected to each other in series and/or parallel.

As the number of the plurality of series acoustic resonators 12, e.g., including series acoustic resonators 12-1, 12-2, 12-3, and 12-4, 13, and 14 included in the series part 10b is increased, heat generation of each of the plurality of series acoustic resonators 12, e.g., including series acoustic resonators 12-1, 12-2, 12-3, and 12-4, 13, and 14 may be reduced, and a probability of damage caused by the heat generation of each of the plurality of series acoustic resonators 12, e.g., including series acoustic resonators 12-1, 12-2, 12-3, and 12-4, 13, and 14 may be decreased.

Among the plurality of series acoustic resonators, some series acoustic resonators 12-1, 12-2, 12-3, and 12-4 may be connected to each other in anti-series. Accordingly, among harmonics mixed in an RF signal passing through the acoustic resonator filter 50b, even-order harmonics may be removed to further improve linearity of the RF signal.

The acoustic resonator filter 50b according to one or more embodiments may further include DC voltage terminals DC11 and DC12, electrically connected to some series acoustic resonators 12-1, 12-2, 12-3, and 12-4, among the plurality of series acoustic resonators, such that a DC voltage is generated between first and second electrodes of one series acoustic resonator 12-1 or 12-3, for example, among the plurality of series acoustic resonators. Herein, a first DC voltage terminal (e.g., DC11) and a second DC terminal (e.g., DC12) may also be referred to collectively as a DC voltage terminal, e.g., configured to generate the DC voltage of the DC voltage terminal DC11 and also configured to generate the DC voltage of the DC voltage terminal DC12. Accordingly, a reference to a DC voltage terminal may refer to one or more DC voltage terminal connections that each generate respective DC voltages across one or more series or shunt resonators, for example. The generation of DC voltage(s) may also refer to the application or provision of respective DC voltages provided to the acoustic resonator filter.

Accordingly, since the process distribution parameters between some series acoustic resonators 12-1, 12-2, 12-3, and 12-4, among the plurality of series acoustic resonators, may be canceled, intermodulation (IMD) characteristics based on harmonics mixed in an RF signal passing through the acoustic resonator filter 50b may be effectively removed, and linearity of the RF signal may be further improved.

For example, the DC voltage terminals DC11 and DC12 may be implemented in the same manner as the DC voltage terminal DC1 of the acoustic resonator filter 50a, and may be electrically connected to some series acoustic resonators 12-1, 12-2, 12-3, and 12-4, among the plurality of series acoustic resonators, such that a DC voltage between first and second electrodes of one series acoustic resonator 12-1 or 12-3, among the plurality of series acoustic resonators, is different from a DC voltage between first and second electrodes of another series acoustic resonator 12-2 or 12-4.

The acoustic resonator filter 50b according to one or more embodiments may include a plurality of shunt parts 20a, 20c, and 20d connected to different nodes of the series part 10b. Each of the plurality of shunt parts 20a, 20c, and 20d may include one or more shunt acoustic resonators 21a, 22a, 23, and 24, as a non-limiting example.

Referring to FIG. 10, an acoustic resonator filter 50c according to one or more embodiments may further include a capacitor Cmod connected, in parallel, to at least one shunt acoustic 21a, among a plurality of shunt acoustic resonators 21a and 22a.

The capacitor Cmod may cancel a difference in characteristics between the plurality of shunt acoustic resonators 21a and 22a depending on the parasitic capacitor Cpara, and a DC voltage terminal DC1 may allow the capacitor Cmod to facilitate cancelation of an effect resulting from a parasitic capacitor Cpara. In another example, an acoustic resonator, a target to which the capacitor Cmod is connected in parallel, may not be the same as an acoustic resonator, a target in which a DC voltage terminal DC1 generates a DC voltage.

Referring to FIG. 1D, a shunt part 20b of an acoustic resonator filter 50d according to one or more embodiments may include a plurality of shunt acoustic resonators 21b and 22b, as non-limiting examples. Each of the plurality of example shunt acoustic resonators 21b and 22b may include a plurality of shunt acoustic resonators 21+, 21−, 22+, and 22− connected to each other in anti-series. That is, the plurality of shunt acoustic resonators 21+ and 21− may be connected to each other in anti-series, and the plurality of shunt acoustic resonators 22+ and 22− may be connected to each other in anti-series.

The DC voltage terminal DC2 may generate a DC voltage between first and second electrodes of one shunt acoustic resonator 21−, among the plurality of shunt acoustic resonators. The DC voltage terminal DC3 may generate a DC voltage between first and second electrodes of one shunt acoustic resonator 22−, among the plurality of shunt acoustic resonators. Accordingly, an effect resulting from the plurality of parasitic capacitors Cpara1 and Cpara2 may be canceled.

Referring to FIG. 1E, a DC voltage terminal DC4 of an acoustic resonator filter 50e according to one or more embodiments may be connected to a plurality of shunt acoustic resonators 21b and 22b in parallel. Accordingly, a DC voltage between first and second electrodes of at least one of the plurality of shunt acoustic resonators may be generated.

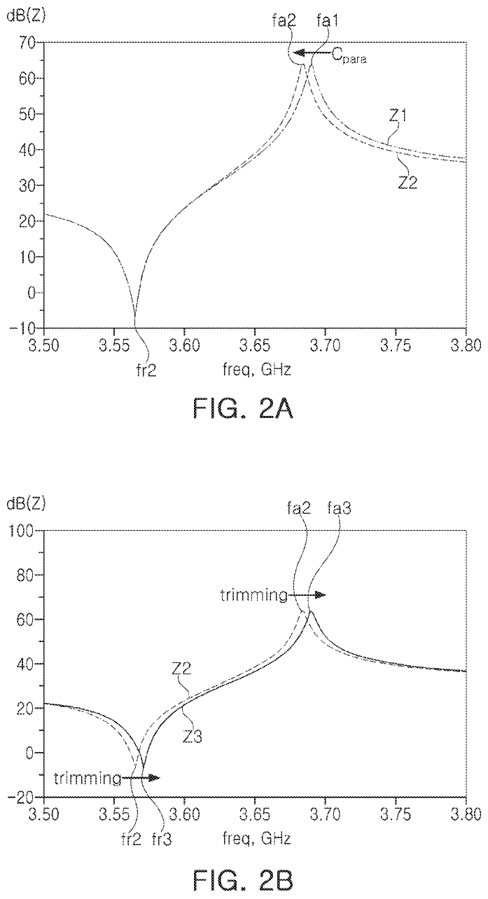

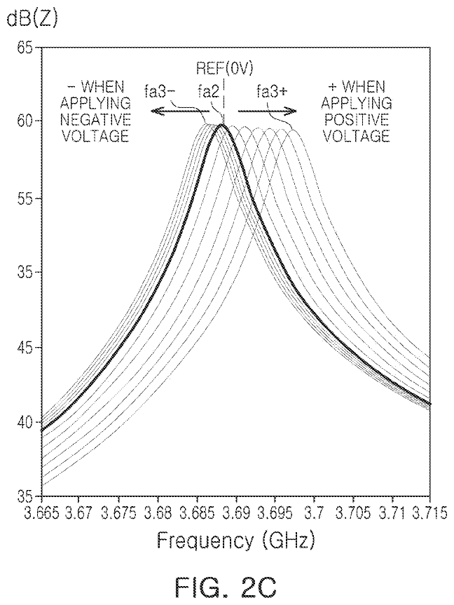

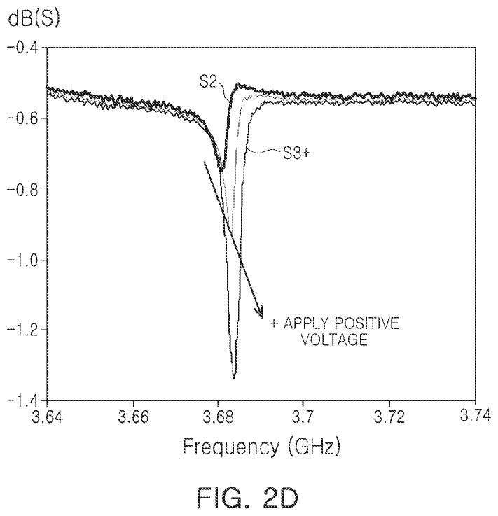

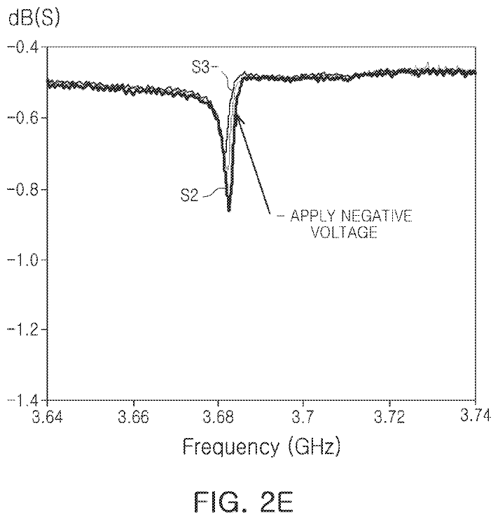

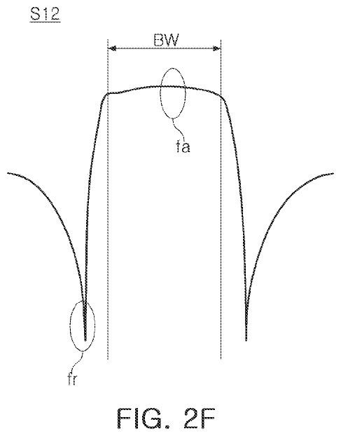

FIGS. 2A to 2F are views illustrating example trimmings of a shunt acoustic resonator of an acoustic resonator filter according to one or more embodiments.

Referring to FIG. 2A, an anti-resonant frequency fa2 of an impedance curve Z2 of a shunt acoustic resonator, which is affected by a parasitic capacitor Cpara, may be lower than an anti-resonant frequency fa1 of an impedance curve Z1 of a shunt acoustic resonator which is not affected by the parasitic capacitor Cpara. A resonant frequency fr2 may be hardly affected by the parasitic capacitor Cpara.

Referring to FIG. 2B, an anti-resonant frequency fa3 and a resonant frequency fr3 of an impedance curve Z3 of a shunt acoustic resonator, in which a DC voltage is generated by a DC voltage terminal, may be increased. The anti-resonant frequency fa3 may be the same as the anti-resonant frequency fa1 of FIG. 2A, for example.

That is, the DC voltage terminal may generate a DC voltage between first and second electrodes of one shunt acoustic resonator, among a plurality of shunt acoustic resonators, such that a difference between a plurality of anti-resonant frequencies of the plurality of shunt acoustic resonators (for example, converging on zero) is smaller than a difference between the plurality of resonant frequencies (for example, a difference between fr2 and fr3). The DC voltage may be formed between the first and second electrodes of one shunt acoustic resonator, among the plurality of shunt acoustic of the resonators.

Referring to FIGS. 2B and 2F, since anti-resonant frequencies fa (e.g., fa2 of FIGS. 2B and 2C) and fa3 may be positioned within a pass bandwidth BW, the anti-resonant frequencies fa and fa3 may have a relatively large effect on the performance of an acoustic resonator filter. In addition, since resonant frequencies fr3 and fr (e.g., fr2 of FIG. 2B) may be positioned outside the pass bandwidth, the resonant frequencies fr3 and fr may have little effect on the performance of the acoustic resonator filter. FIG. 2F illustrates an S-parameter S12 between first and second ports of an acoustic resonator filter.

Accordingly, when the anti-resonant frequency fa3 is trimmed to be closer to the anti-resonant frequency fa1 of FIG. 2A, the performance of the acoustic resonator filter (for example, power durability and removal of harmonics) may be further improved.

A resonant frequency of a series acoustic resonator may be positioned within a pass bandwidth BW, and an anti-resonant frequency of the series acoustic resonator may be positioned outside the pass bandwidth (BW). Accordingly, a difference between a plurality of resonant frequencies of a plurality of shunt acoustic resonators (for example, a difference between fr2 and fr3) may be smaller than a difference between a higher resonant frequency, among the plurality of resonant frequencies, and a resonant frequency of one or more series acoustic resonators.

Referring to FIG. 2C, an anti-resonant frequency fa2 of the shunt acoustic resonator may change to a higher anti-resonant frequency fa3+ when a positive voltage is applied by the DC voltage terminal and may change to a lower anti-resonant frequency fa3− when a negative voltage is applied by the DC voltage terminal.

A moving distance of the anti-resonant frequency fa2 may be dependent on an absolute magnitude of a DC voltage generated by the DC voltage terminal. Accordingly, the absolute magnitude of the DC voltage may be determined based on a difference between the anti-resonant frequency fa2 and the anti-resonant frequency fa1 of FIG. 2A.

Referring to FIG. 2D, a minimum value (or a notch) of an S-parameter S3+ between a plurality of series or shunt acoustic resonators, applied with a positive DC voltage and connected to each other in anti-series, may be lower than a minimum value of an S-parameter S2 of the plurality of series or shunt acoustic resonators in which a DC voltage is zero volt.

Referring to FIG. 2E, a minimum value (or a notch) of an S-parameter S3− of a plurality of series or shunt acoustic resonators, applied with a negative DC voltage and connected to each other in anti-series, may be lower than a minimum value of an S-parameter S2 of a plurality of series or shunt acoustic resonators in which a DC voltage is zero volt.

The lower a minimum value of an S-parameter, the greater a notch of the S-parameter. The smaller the notch, the smaller energy and heat generation concentrated in an acoustic resonator and, thus, the lower a probability of damage to the acoustic resonator. The smaller the notch, the higher a harmonic removal efficiency.

The acoustic resonator according to one or more embodiments may have improved performance (for example, power durability and removal of harmonics) by applying a DC voltage to the acoustic resonator such that the notch is small.

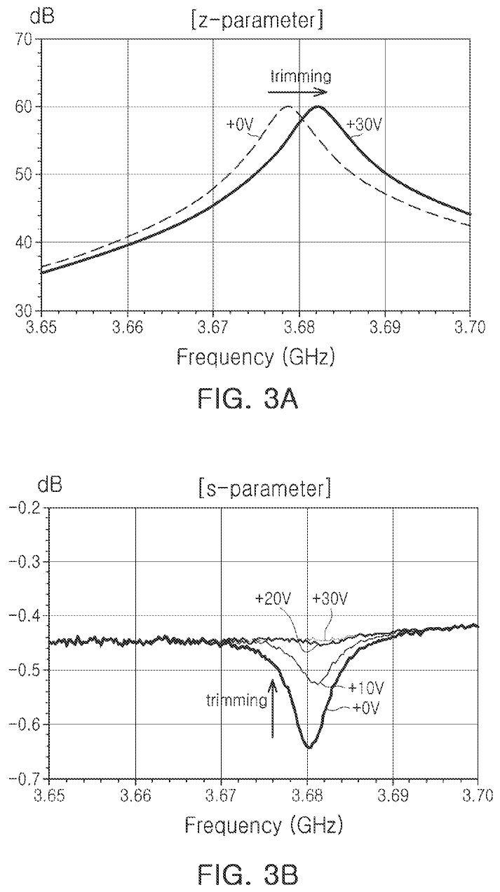

FIGS. 3A and 3B are graphs illustrating removal of a notch depending on various example trimmings of a shunt acoustic resonator of an acoustic resonator filter according to one or more embodiments.

Referring to FIG. 3A, an anti-resonant frequency of impedance characteristics of one shunt acoustic resonator, among the plurality of shunt acoustic resonators of the acoustic resonator filter illustrated in FIG. 1A, may be further increased as a DC voltage of +30V is applied.

Referring to FIG. 3B, a minimum value (or a notch) of an S-parameter of the acoustic resonator filter illustrated in FIG. 1A may be increased as a DC voltage of +10V is applied, and may be significantly close to an average value as a DC voltage higher than +10 V (for example, +20V or +30V) is applied. The greater the minimum value or the smaller the notch, the more the performance of the acoustic resonator filter (for example, power durability and removal of harmonics) may be improved, e.g., compared to no applied DC voltage.

That is, a DC voltage terminal may be configured to generate a DC voltage, having a magnitude higher than 10V, between first and second electrodes of one shunt acoustic resonator, among the plurality of shunt acoustic resonators, and thus, an effect (for example, a notch) resulting from a parasitic capacitor of the plurality of shunt acoustic resonators may be canceled.

In one non-limiting example where the DC voltage applied by the DC voltage terminal is +30V, a performance of a plurality of shunt acoustic resonators (for example, power durability and removal of harmonics) may be optimized. In one or more examples, a magnitude range of the DC voltage applied by the DC voltage terminal may be greater than 10V to 50V or less.

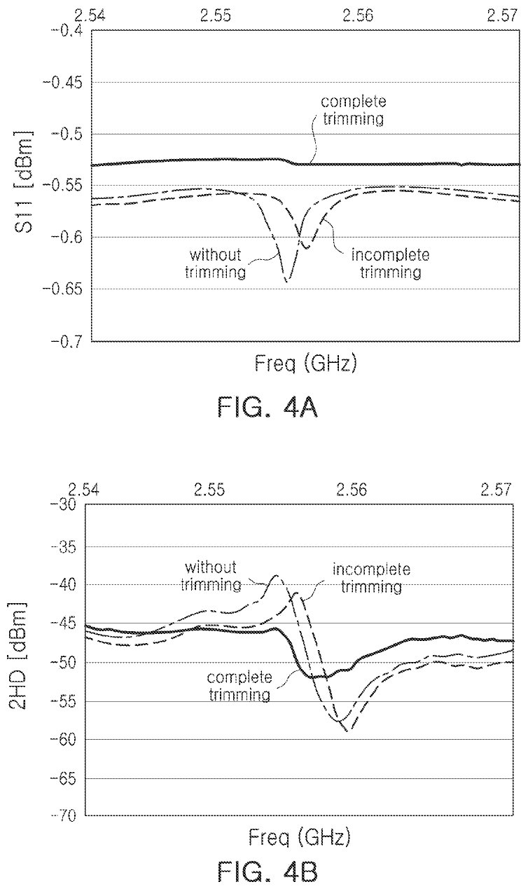

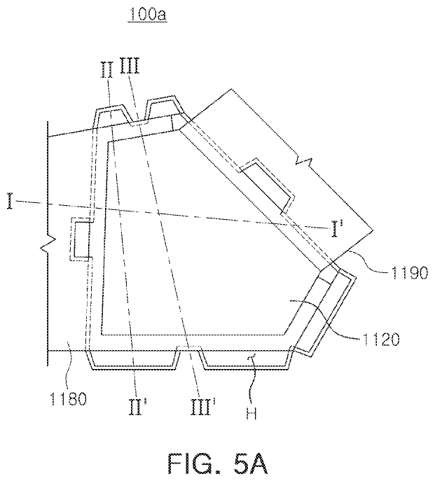

FIGS. 4A and 4B are graphs illustrating removal of a notch and a second harmonic wave depending on example trimmings of a shunt acoustic resonator of an acoustic resonator filter according to one or more embodiments.

Referring to FIGS. 4A and 4B, an acoustic resonator filter according to one or more embodiments may have a pass bandwidth formed at a lower frequency (about 2.5 GHz) than a frequency (about 3.5 GHz) of the acoustic resonator filter of FIGS. 2A to 3B.

Referring to FIG. 4A, a notch of an S-parameter of an acoustic resonator filter, to which a DC voltage is incompletely (e.g., above zero and below the above example 10V) applied (incomplete trimming), may be decreased as compared with a notch of an S-parameter of an acoustic resonator filter to which the DC voltage is not applied by a DC voltage terminal (without trimming). In addition, a notch of an S-parameter of an acoustic resonator filter, to which the DC voltage is completely (e.g., within the above example 10V to 50V range) applied (complete or near complete trimming), may be further decreased.

Referring to FIG. 4B, a second harmonic S-parameter of an acoustic resonator filter, to which a DC voltage is incompletely applied (incomplete trimming), may be uniform as compared with a second harmonic S-parameter of an acoustic resonator filter to which the DC voltage is not trimmed by a DC voltage terminal (without trimming). In addition, a second harmonic S-parameter of an acoustic resonator filter, to which the DC voltage is completely applied (complete trimming), may be further uniform than when the DC voltage is incompletely applied.

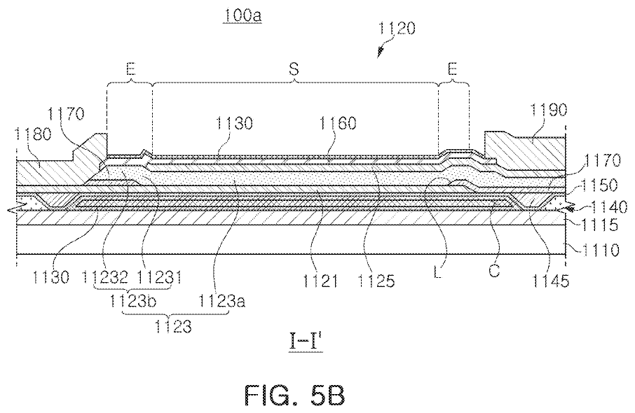

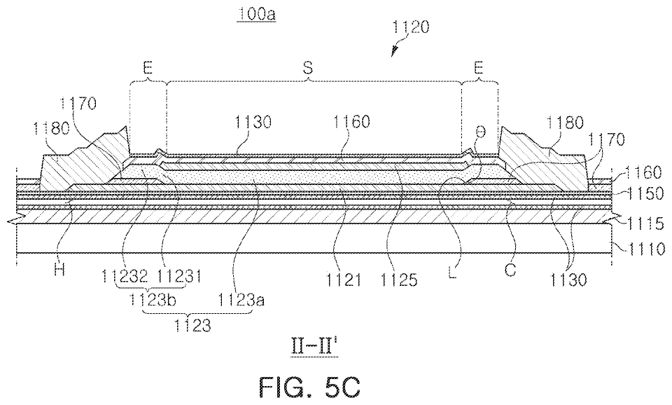

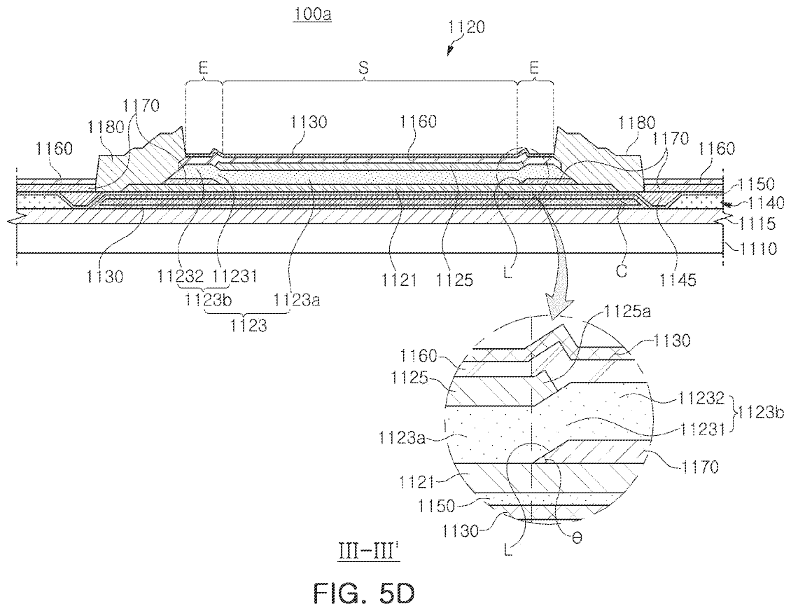

FIG. 5A is a plan view illustrating an example structure of an acoustic resonator which may be included in an acoustic wave resonator filter according to, and of, one or more embodiments, FIG. 5B is an example cross-sectional view taken along line I-I′ of FIG. 5A, FIG. 5C is an example cross-sectional view taken along line II-II′ of FIG. 5A, and FIG. 5D is an example cross-sectional view taken along line III-III′ of FIG. 5A.

Referring to FIGS. 5A to 5D, an acoustic resonator 100a may include a support substrate 1110, an insulating layer 1115, a resonance portion 1120, and a hydrophobic layer 1130.

The support substrate 1110 may be a silicon substrate. As a non-limiting example, a silicon wafer or a silicon-on-insulator (SOI) substrate may be used as the support substrate 1110.

An insulating layer 1115 may be provided on an upper surface of the support substrate 1110 to electrically insulate the support substrate 1110 and the resonance portion 1120 from each other. In addition, the insulating layer 1115 may prevent the support substrate 1110 from being etched by etching gas when a cavity C is formed during the manufacturing of the acoustic resonator 100a.

As non-limiting examples, the insulating layer 1115 may be formed of at least one of silicon dioxide (SiO₂), silicon nitride (Si₃N₄), aluminum oxide (Al₂O₃), and aluminum nitride (AlN), and may be formed by one of a chemical vapor deposition (CVD) process, a radio-frequency (RF) magnetron sputtering process, and an evaporation process.

The support layer 1140 may be formed on the insulating layer 1115, and may be disposed around the cavity C and an etch-stop portion 1145 in the form of surrounding the cavity and the etch-stop portion 1145 inside the support layer 1140.

The cavity C is formed as or to be an empty space, and may be formed by removing a portion of a sacrificial layer formed during the process of providing the support layer 1140, and the support layer 1140 may be formed as a remaining portion of the sacrificial layer.

The support layer 1140 may be formed of an easily etched material such as polysilicon or polymer, but embodiments are not limited thereto.

The etch-stop portion 1145 may be disposed along a boundary of the cavity C. The etch-stop portion 1145 may be provided to prevent the cavity C from being etched beyond a cavity region during the formation of the cavity C.

A membrane layer 1150 may be formed on the support layer 1140, and may constitute an upper surface of the cavity C. Accordingly, the membrane layer 1150 may also be formed of a material that is not easily removed during the formation of the cavity C.

In a non-limiting example, when halide-based etching gas such as fluorine (F) or chlorine (Cl) is used to remove a portion (for example, a cavity region) of the support layer 1140, the membrane layer 1150 may be formed of a material having low reactivity with the above etching gas. In this case, the membrane layer 1150 may include at least one of silicon dioxide (SiO₂) and silicon nitride (Si₃N₄), as non-limiting examples.

In addition, the membrane layer 1150 may be formed as a dielectric layer including at least one of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), zinc oxide (ZnO), or as a metal layer including at least one of aluminum (Al), nickel (Ni), chromium (Cr), platinum (Pt), gallium (Ga), and hafnium (Hf), noting that embodiments are not limited thereto.

The resonance portion 1120 may include a first electrode 1121, a piezoelectric layer 1123, and a second electrode 1125. In the resonance portion 1120, the first electrode 1121, the piezoelectric layer 1123, and the second electrode 1125 may be sequentially stacked from below. Accordingly, in the resonance portion 1120, the piezoelectric layer 1123 may be disposed between the first electrode 1121 and the second electrode 1125.

Since the resonance portion 1120 is formed on the membrane layer 1150, the membrane layer 1150, the first electrode 1121, the piezoelectric layer 1123, and the second electrode 1125 may be sequentially stacked on the support substrate 1110 to constitute the resonance portion 1120.

The resonance portion 1120 may resonate the piezoelectric layer 1123 in response to a signal, applied to the first electrode 1121 and the second electrode 1125, to generate a resonant frequency and an anti-resonant frequency.

The resonance portion 1120 be divided into a central portion S, in which the first electrode 1121, the piezoelectric layer 1123, and the second electrode 1125 are stacked to be approximately flat, and an extension portion E in which an insertion layer 1170 is interposed between the first electrode 1121 and the piezoelectric layer 1123.

The central portion S may be a region disposed in the center of the resonance portion 1120, and the extension portion E may be a region disposed along a periphery of the central portion S. Therefore, the extension portion E may be a region extending outwardly from the central portion S, and may refer to a region formed in a continuous annular shape along the circumference of the central potion S. However, in an example, the extension portion E may be formed in a discontinuous annular shape in which some regions of the extension portion E thereof are disconnected.

Accordingly, as illustrated in FIG. 5B, in the cross-section of the resonance portion 1120 taken to traverse the central portion S, the extension portion E may be disposed on both ends of the central portion S. In addition, the insertion layer 1170 may be disposed on both sides of the extension portion E disposed on both ends of the central portion S.

The insertion layer 1170 may have an inclined surface L having a thickness increased in a direction away from the central portion S.

In the extension portion E, the piezoelectric layer 1123 and the second electrode 1125 may be disposed on the insertion layer 1170. Accordingly, the piezoelectric layer 1123 and the second electrode 1125 disposed in the extension portion E may have inclined surfaces conforming to a shape of the insertion layer 1170.

The extension portion E may be defined as being included in the resonance portion 1120. Accordingly, resonance may also occur in the extension portion E, but embodiments are not limited thereto. In an example, depending on the structure of the extension portion E, resonance may not occur in the extension portion E but resonance may occur only in the central portion S.

The first electrode 1121 and the second electrode 1125 may be formed of a conductive material, for example, gold, molybdenum, ruthenium, iridium, aluminum, platinum, titanium, tungsten, palladium, tantalum, chromium, nickel, or a metal including at least one thereof, but the conductive material is not limited thereto.

In the resonance portion 1120, the first electrode 1121 may formed to have a larger area than the second electrode 1125, and a first metal layer 1180 may be disposed on the first electrode 1121 along an external periphery of the first electrode 1121. Accordingly, the first metal layer 1180 may be disposed to be spaced apart from the second electrode 1125 by a predetermined distance, and may be disposed in the form of surrounding the resonance portion 1120.

Since the first electrode 1121 is disposed on the membrane layer 1150, the first electrode 1121 may be formed to be overall flat, as a non-limiting example. On the other hand, since the second electrode 1125 is disposed on the piezoelectric layer 1123, the second electrode 1125 may be bent to correspond to a shape of the piezoelectric layer 1123, e.g., depending on the insertion layer 1170.

The first electrode 1121 may be used as one of an input electrode and an output electrode for respectively inputting and outputting an electrical signal such as a radio-frequency (RF) signal.

The second electrode 1125 may be entirely disposed in the central portion S, and may be partially disposed in the extension portion E. Accordingly, the second electrode 1125 may be divided into a portion, disposed on the piezoelectric portion 1123a of the piezoelectric layer 1123 to be described later, and a portion disposed on a bent portion 1123b of the piezoelectric layer 1123.

For example, the second electrode 1125 may be disposed in the form of covering the entirety of the piezoelectric portion 1123a and a portion of the inclined portion 11231 of the piezoelectric layer 1123. Therefore, the second electrode (1125a of FIG. 5D) disposed in the extension portion E may be formed to have a smaller area than the inclined surface of the inclined portion 11231, and the second electrode 1125 in the resonance portion 1120 may be formed to have a smaller area than the piezoelectric layer 1123.

Accordingly, as illustrated in FIG. 5B, in a cross-section of the resonance portion 1120 taken to traverse the central portion S, an end of the second electrode 1125 may be disposed in the extension portion E. In addition, an end of the second electrode 1125 disposed in the extension portion E may be disposed such that at least a portion thereof overlaps the insertion layer 1170. The term “overlap” means that when the second electrode 1125 is projected to a plane on which the insertion layer 1170 is disposed, a shape of the second electrode 1125 projected to the plane coincides in space with the insertion layer 1170.

The second electrode 1125 may be used as one of an input electrode and an output electrode for inputting and outputting an electrical signal such as a radio-frequency (RF) signal. For example, the second electrode 1125 may be used as an output electrode when the first electrode 1121 is used as an input electrode, and the second electrode 1125 may be used as an input electrode when the first electrode 1121 is used as an output electrode.

As illustrated in FIG. 5D, when the end of the second electrode 1125 is disposed on the inclined portion 11231 of the piezoelectric layer 1123 to be described later, acoustic impedance of the resonance portion 1120 may be formed to have a sparse/dense/sparse/dense structure from the center portion S outward to increase a reflective interface reflecting a lateral wave inwardly of the resonance portion 1120. Accordingly, most or at least a majority of the lateral waves do not escape outside of the resonance portion 1120 but are reflected inwardly of the resonance portion 1120, so that performance of the acoustic wave resonator may be improved.

The piezoelectric layer 1123 may create a piezoelectric effect to convert electrical energy into mechanical energy in an elastic wave form, and may be formed on the first electrode 1121 and the insertion layer 1170.

As a non-limiting example, Zinc oxide (ZnO), aluminum nitride (AlN), doped aluminum nitride, lead zirconate titanate (PZT), quartz, or the like, may be selectively used as a material of the piezoelectric layer 123. The doped aluminum nitride may further include a rare earth metal, a transition metal, or an alkaline earth metal, for example. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). The alkaline earth metal may include magnesium (Mg), noting that examples are not limited to these transition or alkaline earth metals. The content of elements doped into aluminum nitride (AlN) may be in the range of 0.1 to 30 at %.

The piezoelectric layer may be used by doping aluminum nitride (AlN) with scandium (Sc), as a non-limiting example. In such doping examples, a piezoelectric constant may be increased, so that Kt² of the acoustic resonator may also be increased.

The piezoelectric layer 1123 may include a piezoelectric portion 1123a, disposed in the central portion S, and a bent portion 1123b disposed in the extension portion E.

The piezoelectric portion 1123a may be directly stacked on an upper surface of the first electrode 1121. Accordingly, the piezoelectric portion 1123a may be interposed between the first electrode 1121 and the second electrode 1125, and may be formed to be flat along with the first electrode 1121 and the second electrode 1125.

The bent portion 1123b may be defined as a region extending outwardly from the piezoelectric portion 1123a to a position in the extension portion E.

The bent portion 1123b may be disposed on the insertion layer 1170 to be described later, and may be formed to have a shape, in which an upper surface is uplifted, conforming to the insertion layer 1170. In this regard, the piezoelectric layer 1123 may be bent at a boundary of the piezoelectric portion 1123a and the bent portion 1123b, and the bent portion 1123b may be uplifted to correspond to a thickness and a shape of the insertion layer 1170.

The bent portion 1123b may be divided into an inclined portion 11231 and an extension portion 11232.

The inclined portion 11231 may refer to a portion formed to be inclined along the inclined surface L of the insertion layer 1170 to be described later. In addition, the extension portion 11232 may refers to a portion extending outwardly from the inclined portion 11231.

The inclined portion 11231 may be formed to be parallel to the inclined surface L of the insertion layer 1170, and an angle of inclination of the inclined portion 11231 may be the same as an angle of inclination of the inclined surface L of the insertion layer 1170.

The insertion layer 1170 may be disposed along a surface defined by the membrane layer 1150, the first electrode 1121, and the etch-stop portion 1145. Accordingly, the insertion layer 1170 may be partially disposed in the resonance portion 1120 and may be disposed between the first electrode 1121 and the piezoelectric layer 1123.

The insertion layer 1170 may be disposed around the central portion S to support the bent portion 1123b of the piezoelectric layer 1123. Accordingly, the bent portion 1123b of the piezoelectric layer 1123 may be divided into an inclined portion 11231 and an extension portion 11232 according to the shape of the insertion layer 1170.

The insertion layer 1170 may be disposed in a region excluding the center portion S. For example, the insertion layer 1170 may be disposed on the entire substrate 1110 excluding a center portion S thereof or a portion of the substrate 1110 excluding the center portion S.

A thickness of the insertion layer 1170 may be increased in a direction away from the center portion S. As a non-limiting example, a side surface of the insertion layer 1170 adjacent to the central portion S may be an inclined surface L having a predetermined angle of inclination θ. In a non-limiting example, the angle of inclination θ of the inclined surface L may be 5° or more, 70° or less (i.e., and greater than 0°), or in a range of 5° or more to 70° or less.

The inclined portion 11231 of the piezoelectric layer 1123 may be formed along the inclined surface L of the insertion layer 1170, and may be formed at the same angle of inclination as the inclined surface L of the insertion layer 1170. Accordingly, in an example, the angle of inclination of the inclined portion 11231 may be in the range of 5° or more to 70° or less, similarly or corresponding to the inclined surface L of the insertion layer 1170. It is apparent that such a configuration is equivalently applied to the second electrode 1125 stacked on the inclined surface L of the insertion layer 1170.

The insertion layer 1170 may be formed of a dielectric substance such as silicon dioxide (SiO₂), aluminum nitride (AlN), aluminum oxide (Al₂O₃), silicon nitride (Si₃N₄), manganese oxide (MnO), zirconium oxide (ZrO₂), lead zirconate titanate (PZT), gallium arsenide (GaAs), hafnium oxide (HfO₂), titanium oxide (TiO₂), zinc oxide (ZnO), or the like, but may be formed of a material different from that of the piezoelectric layer 1123.

In addition, the insertion layer 1170 may be implemented with a metal. Since a large amount of heat is generated in the resonance portion 1120 when the acoustic resonator 100 is used in 5G communications, the heat generated in the resonance portion 1120 may desirably be smoothly released. To this end, as only an example, the insertion layer 1170 may be formed of an aluminum alloy containing Sc.

The resonance portion 1120 may be spaced apart from the support substrate 1110 through a cavity C formed as an empty space.

The cavity C may be formed by supplying etching gas (or an etching solution) through an inflow hole (H of FIG. 5A) to remove a corresponding portion of the sacrificial layer 1140 during the manufacturing of the acoustic resonator.

Accordingly, the cavity C may have an upper surface (a ceiling surface) and a side surface (a wall surface) defined by the membrane layer 1150, and may be provided as a space in which a bottom surface thereof is defined by the support substrate 1110 or the insulating layer 1115. The membrane layer 1150 may or may not be formed only on the upper surface (the ceiling surface) of the cavity C, depending on different example orders of the corresponding manufacturing method.

The protective layer 1160 may be disposed along a surface of the acoustic resonator 100a to protect the acoustic resonator 100a from an external environment. The protective layer 1160 may be disposed along a surface defined by the second electrode 1125 and the bent portion 1123b of the piezoelectric layer 1123.

The protective layer 1160 may be partially removed to adjust a frequency in a final process during the manufacturing process. For example, a thickness of the protective layer 1160 may be adjusted through frequency trimming during the manufacturing process.

To this end, the protective layer 1160 may include one of silicon dioxide (SiO₂), silicon nitride (Si₃N₄), magnesium oxide (MgO), zirconium oxide (ZrO₂), aluminum nitride (AlN), lead zirconate titanate (PZT), gallium Arsenic (GaAs), hafnium oxide (HfO2), aluminum oxide (Al₂O₃), titanium oxide (TiO₂), zinc oxide (ZnO), amorphous silicon (a-Si), and polycrystalline silicon (p-Si), which are appropriate to the frequency trimming, but embodiments are not limited thereto.

The first electrode 1121 and the second electrode 1125 may extend outwardly of the resonance portion 1120. In addition, a first metal layer 1180 and a second metal layer 1190 may each be disposed on an upper surface of a portion formed by extension.

The first metal layer 1180 and the second metal layer 1190 may be formed of one of gold (Au), a gold-tin (Au—Sn) alloy, copper (Cu), a copper-tin (Cu—Sn) alloy, aluminum (Al), and an aluminum alloy, as non-limiting examples. The aluminum alloy may be an aluminum-germanium (Al—Ge) alloy or an aluminum-scandium (Al—Sc) alloy, as non-limiting examples.

The first metal layer 1180 and the second metal layer 1190 may function as a connection wiring for electrically connecting each of the electrodes 1121 and 1125 of the acoustic resonator to an electrode of another acoustic resonator disposed adjacent to each other, on the support substrate 1110.

At least a portion of the first metal layer 1180 may be in contact with the passivation layer 1160 and may be bonded to the first electrode 1121.

In the resonance portion 1120, the first electrode 1121 may be formed to have a larger area than the second electrode 1125, and the first metal layer 1180 may be formed on a peripheral portion of the first electrode 1121.

Accordingly, the first metal layer 1180 may be disposed along the periphery of the resonance portion 1120, and may be disposed in the form of surrounding the second electrode 1125. However, embodiments are not limited thereto.

In the acoustic resonator, a hydrophobic layer 1130 may be disposed on a surface of the protective layer 1160 and an internal wall of the cavity C. The hydrophobic layer 1130 may suppress adsorption of water and a hydroxyl group (an OH group) to significantly reduce frequency fluctuation, and thus, the resonator performance may be maintained to be uniform.

The hydrophobic layer 1130 may be formed of a self-assembled monolayer (SAM) forming material, rather than a polymer. When the hydrophobic layer 1130 is formed of a polymer, mass loading resulting from the polymer may affect the resonance portion 1120. However, in an example, since the hydrophobic layer 1130 of the acoustic resonator is formed of a self-assembled monolayer, a fluctuation in resonant frequency of the acoustic resonator may be significantly reduced. In addition, a thickness of the hydrophobic layer 1130 depending on a position in the cavity C may be uniform.

The hydrophobic layer 1130 may be formed by vapor-depositing a precursor having hydrophobicity. In this case, the hydrophobic layer 1130 may be deposited as a monolayer having a thickness of 100 A or less (for example, several A to several tens of A). The precursor material having hydrophobicity may be or include a material having a water-contact angle of 90° or more after deposition. For example, the hydrophobic layer 1130 may contain a fluorine (F) component, and may include fluorine (F) and silicon (Si), as non-limiting examples. For example, fluorocarbon having a silicon head may be used, but embodiments are not limited thereto.

Before the hydrophobic layer 1130 is formed, a bonding layer may be formed on the surface of the protective layer 1160 in the method of manufacture to improve adhesive strength between the self-assembled monolayer, constituting the hydrophobic layer 1130, and the protective layer 1160.

The bonding layer may be formed by vapor-depositing a precursor, having a hydrophobic functional group, on the surface of the protective layer 1160.

As a precursor used for deposition of the bonding layer, hydrocarbon having a silicon head or siloxane having a silicon head may be used, but embodiments are not limited thereto.

Since the hydrophobic layer 1130 is formed after the first metal layer 1180 and the second metal layer 1190 are formed, the hydrophobic layer 1130 may be formed along surfaces of the protective layer 1160, the first metal layer 1180, and the second metal layer 1190.

In the drawings, the hydrophobic layer 1130 is illustrated as being not disposed on the surfaces of the first metal layer 1180 and the second metal layer 1190. However, embodiments are not limited to such an example, and the hydrophobic layer 1130 may also be disposed on the surface of the metal layer 1190.

In addition, the hydrophobic layer 1130 may be disposed on an internal surface of the cavity C as well as the upper surface of the protective layer 1160.

The hydrophobic layer 1130, formed in the cavity C, may be formed on an entire internal wall forming the cavity C. Accordingly, the hydrophobic layer 1130 may also be formed on a lower surface of the membrane layer 1150 defining a lower surface of the resonance portion 1120. In this case, for example, adsorption of a hydroxyl group to the lower portion of the resonance portion 1120 may be suppressed.

The adsorption of the hydroxyl group may occur not only in the protective layer 1160 but also in the cavity C. Therefore, for example, the adsorption of the hydroxyl group may be blocked not only in the protective layer 1160 but also in an upper surface of the cavity C (a lower surface of the membrane layer), a lower surface of the resonance portion, to significantly reduce mass loading caused by the adsorption of the hydroxyl group and a decrease in frequency caused by the mass loading.

In addition, when the hydrophobic layer 1130 is formed on upper and lower surfaces or a side surface of the cavity C, a stiction phenomenon in which the resonance portion 1120 is stuck to the insulating layer 1115 by surface tension may be suppressed in a wet process or a cleaning process of the method of manufacture after the formation of the cavity C.

The example, in which the hydrophobic layer 1130 is formed on the entire internal wall of the cavity C, has been described, but embodiments are not limited thereto. Various examples also exist, such as forming the hydrophobic layer 1130 only on the upper surface of the cavity C and forming the hydrophobic layer 1130 only in a portion of the lower and side surfaces of the cavity C, may be made.

As described above, an acoustic resonator filter according to one or more embodiments may further improve performance of canceling even-order harmonics having an anti-series structure, and thus, linearity of an RF signal passing through the acoustic resonator filter may be further improved.

In addition, an acoustic resonator filter according to one or more embodiments may local concentration of power, caused by a parasitic capacitor or process distribution parameters, to have further improved power durability.

While specific examples have been illustrated and described above, it will be apparent after gaining an understanding of this disclosure that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An acoustic resonator filter comprising:
a series portion of the acoustic resonator filter, the series portion including at least one series acoustic resonator electrically connected, in series, between first and second ports of the acoustic resonator filter configured to pass a radio-frequency (RF) signal from the first port to the second port;
a shunt portion of the acoustic resonator filter, the shunt portion including a plurality of shunt acoustic resonators electrically connected to each other, in anti-series, between one node of the series portion and a ground; and
a DC voltage terminal configured to generate a DC voltage across at least one of the plurality of shunt acoustic resonators by an electrical connection of the DC voltage terminal to a first electrode of the at least one of the plurality of shunt acoustic resonators and to a different second electrode of the at least one of the plurality of shunt acoustic resonators.

2. The acoustic resonator filter of claim 1, wherein the DC voltage terminal is configured to generate the DC voltage between a node, between two of the plurality of shunt acoustic resonators, and the ground.

3. The acoustic resonator filter of claim 1, wherein the DC voltage terminal is configured to generate a first DC voltage across at least one first shunt acoustic resonator of the at least one of the plurality of shunt acoustic resonators that is different from a DC voltage across at least one other shunt acoustic resonator of the plurality of shunt acoustic resonators when the first DC voltage is generated.

4. The acoustic resonator filter of claim 1, wherein the at least one series acoustic resonator includes a plurality of series acoustic resonators, and
the DC voltage terminal is further configured to generate another DC voltage across at least one of the plurality of series acoustic resonators by another electrical connection of the DC voltage terminal to a first electrode of the at least one of the plurality of series acoustic resonators and to a different second electrode of the at least one of the plurality of series acoustic resonators.

5. The acoustic resonator filter of claim 1, wherein, with the DC voltage terminal configured to generates the DC voltage, a difference between a plurality of anti-resonant frequencies of the plurality of shunt acoustic resonators is smaller than a difference between a plurality of resonant frequencies of the plurality of shunt acoustic resonators when the DC voltage is generated.

6. The acoustic resonator filter of claim 1, wherein the DC voltage terminal is configured to generate the DC voltage to have a magnitude greater than 10V.

7. The acoustic resonator filter of claim 6, wherein the DC voltage terminal is further configured to generate the DC voltage to have a magnitude of 50V or less.

8. The acoustic resonator filter of claim 1, further comprising:
a capacitor connected electrically, in parallel, with one or more shunt acoustic resonators of the at least one of the plurality of shunt acoustic resonators.

9. The acoustic resonator filter of claim 8, wherein the at least one of the plurality of shunt acoustic resonators includes two or more of the plurality of shunt acoustic resonators, and the one or more shunt acoustic resonators is a single shunt acoustic resonator.

10. An acoustic resonator filter comprising:
a series portion of the acoustic resonator filter, the series portion including a plurality of series acoustic resonators electrically connected, in anti-series, between first and second ports of the acoustic resonator filter configured to pass a radio-frequency (RF) signal from the first port to the second port;
a shunt portion of the acoustic resonator filter, the shunt portion including at least one shunt acoustic resonator electrically connected between one node of the series portion and a ground; and
a DC voltage terminal configured to generate a DC voltage across at least one of the plurality of series acoustic resonators by an electrical connection of the DC voltage terminal to a first electrode of the at least one of the plurality of series acoustic resonators and to a different second electrode of the at least one of the plurality of series acoustic resonators.

11. The acoustic resonator filter of claim 10, wherein the DC voltage terminal is configured to generate a first DC voltage across at least one first series acoustic resonator of the at least one of the plurality of series acoustic resonators that is different from a DC voltage across at least one other series acoustic resonator of the plurality of series acoustic resonators when the first DC voltage is generated.

12. The acoustic resonator filter of claim 10, wherein, with the DC voltage terminal configured to generates the DC voltage, a difference between a plurality of anti-resonant frequencies of the plurality of series acoustic resonators is smaller than a difference between a plurality of resonant frequencies of the plurality of series acoustic resonators when the DC voltage is generated.

13. The acoustic resonator filter of claim 10, wherein the DC voltage terminal is configured to generate the DC voltage to have a magnitude greater than 10V.

14. An acoustic resonator comprising:
a series portion of the acoustic resonator filter, the series portion including at least one series acoustic resonator electrically connected, in series, between first and second ports of the acoustic resonator filter configured to pass a radio-frequency (RF) signal from the first port to the second port;
a shunt portion of the acoustic resonator filter, the shunt portion including a plurality of shunt acoustic resonators electrically connected to each other between one node of the series portion and a ground; and
a DC voltage terminal configured to generate a DC voltage across at least one of the plurality of shunt acoustic resonators by an electrical connection of the DC voltage terminal to a first electrode of the at least one of the plurality of shunt acoustic resonators and to a different second electrode of the at least one of the plurality of shunt acoustic resonators, and
wherein, with the DC voltage terminal configured to generates the DC voltage, a difference between a plurality of anti-resonant frequencies of the plurality of shunt acoustic resonators is smaller than a difference between a plurality of resonant frequencies of the plurality of shunt acoustic resonators when the DC voltage is generated.

15. The acoustic resonator filter of claim 14, wherein, with the DC voltage terminal configured to generates the DC voltage, the difference between the plurality of resonant frequencies of the plurality of shunt acoustic resonators is smaller than a difference between a resonant frequency, among the plurality of resonant frequencies, and a resonant frequency of the at least one series acoustic resonator when the DC voltage is generated, and
wherein the resonant frequency, among the plurality of resonant frequencies, is higher than the resonant frequency of the at least one series acoustic resonator.

16. The acoustic resonator filter of claim 14, wherein the series portion and the shunt portion provide a pass band,
each of the plurality of anti-resonant frequencies of the plurality of shunt acoustic resonators are positioned within the pass band, and
each of the plurality of resonant frequencies of the plurality of shunt acoustic resonators are positioned outside the pass band.

17. The acoustic resonator filter of claim 14, wherein the DC voltage terminal is configured to generate the DC voltage between a node, between two of the plurality of shunt acoustic resonators, and the ground.

18. The acoustic resonator filter of claim 14, wherein the DC voltage terminal is configured to generate the DC voltage to have a magnitude greater than 10V.

19. The acoustic resonator filter of claim 18, wherein the DC voltage terminal is further configured to generate the DC voltage to have a magnitude of 50V or less.

20. The acoustic resonator filter of claim 14, further comprising:
a capacitor connected electrically, in parallel, with one or more shunt acoustic resonators of the plurality of shunt acoustic resonators.
